(19) United States
(12) Patent Application Publication
(10) Pub. No.: US 2018/0158620 A1
(43) Pub. Date: Jun. 7, 2018

(54) DYE-SENSITIZED SOLAR CELL

(71) Applicant: Orion Co., Ltd., Gumi-si, Gyeongsangbuk-do (KR)

(72) Inventors: Jae Kwon Cho, Gumi-si (KR); Jae Kwun Hwang, Gumi-si (KR)

(21) Appl. No.: 15/577,277

(22) PCT Filed: Jun. 15, 2016
(86) PCT No.: PCT/KR2016/006343

§ 371 Date: Nov. 27, 2017

(30) Foreign Application Priority Data
Jun. 16, 2015 (KR) 10-2015-0084905

(51) Int. Cl. H01G 9/20; H01L 31/042

(52) U.S. Cl. CPC H01G 9/2059; H01G 9/2004; B32B 2457/12; H01L 31/042; H01G 9/2031; H01G 9/2077

(57) ABSTRACT

The present invention relates to a dye-sensitized solar cell, and in the present invention, in order to substantially increase the overall outer path line of the electrolyte injection hole, a structure of a corresponding electrolyte injection hole is improved such that the structure comprises: an inlet part exposed to the outside of a reception cell; a delivery part, which extends in a direction differing from that of the inlet part while being connected to the inlet part; and an outlet part, which extends in a direction differing from that of the delivery part while being connected to the delivery part and the reception cell, thereby inducing a large increase in the overall path of a tiny gap, which is formed between an interface of the electrolyte injection hole and a bonding stopper filled in the electrolyte injection hole.

### TECHNICAL FIELD

The present disclosure relates to a dye-sensitized solar cell, and more particularly, to a dye-sensitized solar cell in which in order to substantially increase the overall outer path line of an electrolyte injection hole, a structure of the corresponding electrolyte injection hole is improved such that the structure includes an inlet part exposed to the outside of a reception cell, a delivery part connected to the inlet part and extending in a different direction from the inlet part, and an outlet part connecting the delivery part and the reception cell and extending in a different direction from the delivery part, thereby inducing a significant increase in the outer profile of a bonding stopper filled in the electrolyte injection hole, and through this, inducing a large increase in the overall path of a tiny gap formed at an interface between the bonding stopper and the electrolyte injection hole, so as to solve problems such as the immediate outflow, to the outside, of an electrolyte through the tiny gap having a short path, and the immediate inflow of contaminants (for example, moisture, gas, oil, various types of chemicals, etc.) thereinto through the tiny gap having a short path at the side of the agent of production, such that the overall quality of a product is improved.

### BACKGROUND ART

As shown in FIG. 1, a conventional dye-sensitized solar cell 10 has a systematic combination of upper and lower plates 21, 22 made of glass with upper and lower electrodes 51, 52, an electrolyte/dye reception cell 30 interposed between the upper and lower plates 21, 22 and separated by an internal barrier 40 and receiving an electrolyte or a dye polymer, and a grid electrode 53 inserted into the internal barrier 40 and separated from the electrolyte. In this case, the upper and lower plates 21, 22 may be coated with a conductive material (not shown), for example, FTO. A plurality of reception cells 130 may be arranged along the upper and lower plates 121, 122.

A further detailed structure of the dye-sensitized solar cell 10 is disclosed by, for example, Korean Patent Publication No. 10-2012-114888 (titled sealing material for dye-sensitized solar cell and method for sealing dye-sensitized solar cell using the same) (published Oct. 17, 2012) and Korean Patent No. 10-1223736 (titled electrolyte for dye-sensitized solar cell and dye-sensitized solar cell using the same) (published Jan. 21, 2013).

Meanwhile, in this conventional structure, when the upper plate 21 and the lower plate 22 that constitute the dye-sensitized solar cell 10 are assembled/combined into a sandwich form by the medium of the internal barrier 40, a process of injecting an electrolyte and a dye polymer through an electrolyte injection hole 60 formed on the side of the upper and lower plates 21, 22 is performed at the side of the agent of production.

Unless any separate additional action is taken after injecting the electrolyte and the dye polymer, a serious problem with the outflow of the corresponding electrolyte to the outside may occur, and thus a series of sealing processes is performed at the side of the agent of production to place a sealing structure 70 at the outer periphery of the upper and lower plates 21, 22, thereby preventing the outflow of the electrolyte to the outside.

For example, Korean Patent Publication No. 10-2010-116797 (titled sealing device for solar cell and its control method) (published Nov. 2, 2010), and Korean Patent Publication No. 10-2013-23929 (titled electrolyte sealing structure of dye-sensitized solar cell) (published Mar. 8, 2013) disclose the embodiments of conventional electrolyte sealing methods in more detail.

Meanwhile, in the conventional structure, although the agent of production spent their time/cost in additionally placing the sealing structure 70, a situation may occur in which when the dye-sensitized solar cell 10 is placed in many abnormal situations as described below, the electrolyte within the upper and lower plates 21, 22 passes through or runs over the sealing structure 70 and flows outward.

For example, although the sealing structure 70 is additionally placed, a situation may occur in which the electrolyte within the upper and lower plates 21, 22 unfavorably passes through or runs over the sealing structure 70 and flows outward at the initial step of the sealing process in which the sealing structure 70 is not yet cured.

Furthermore, when the assembled upper and lower plates 21, 22 are illuminated with direct rays of light, and with the increasing internal temperature and pressure of the upper and lower plates 21, 22, the upper and lower plates 21, 22 are spread apart at a predetermined distance or more, likewise, although the sealing structure 70 is additionally placed, a situation may occur in which the electrolyte within the upper and lower plates 21, 22 unfavorably passes through or runs over the sealing structure 70 and flows outward.

Further, when bonding between the sealing structure 70 and the upper and lower plates 21, 22 is in bad condition due to a cleaning fault in the upper and lower plates 21, 22, although the sealing structure 70 is additionally placed, a situation may occur in which the electrolyte within the upper and lower plates 21, 22 unfavorably passes through or runs over the sealing structure 70 and flows outward.

Particularly, in the conventional structure, the sealing structure 70 is made of, for example, vanadate and silicate, and thus has a strong effect on the confinement of the electrolyte filled in the sealing structure 70, but has a very low effect on the prevention of ingression/penetration of many contaminants, for example, moisture, gas, oil, various types of chemicals, etc. from the outside into the upper and lower plates 21, 22. Accordingly, in the conventional structure, the inside of the upper and lower plates 21, 22 may sustain serious damage when polluted by many contaminants (for example, moisture, gas, oil, various types of chemicals, etc.) entering inside, and reliability of finally produced solar cells will be greatly reduced under a serious pollution situation inside of the upper and lower plates 21, 22.

To solve many problems described in the foregoing, the conventional art forms a bonding stopper 80 in the electrolyte injection hole 60 to solve the electrolyte outflow problem and the inflow problem of contaminants (for example, moisture, gas, oil, various types of chemicals, etc.) as shown in FIG. 1.

However, despite formation and placement of the bonding stopper 80, there is difficulty in perfectly solving the electrolyte outflow problem and the inflow problem of contaminants (for example, moisture, gas, oil, various types of chemicals, etc.).

This is because the conventional electrolyte injection hole 60 has a “11” shaped profile structure in which an inlet and an outlet are connected with a straight line, leading to a very short overall outer path line, and the bonding stopper 80 filled/formed to the size of the electrolyte injection hole 60 also has a short outer profile according to the structure of the electrolyte injection hole 60, and accordingly, a tiny gap T formed at the interface of the bonding stopper 80 and the electrolyte injection hole 60 also has a very short overall path, causing the immediate outflow of the electrolyte to the outside or the immediate inflow of contaminants (for example, moisture, gas, oil, various types of chemicals, etc.) inside through the tiny gap T having a short path.

Of course, if the creation of the tiny gap T is perfectly prevented, the above problems may be solved to some extent, but under the conventional technical conditions, there are many difficulties in perfectly preventing the tiny gap T from being created, and as a result, in spite of additionally placing the bonding stopper 80, the agent of production cannot avoid the product quality degradation problem caused by electrolyte outflow or contaminants inflow.

### DISCLOSURE

### Technical Problem

Therefore, the present disclosure aims to improve a structure of the electrolyte injection hole of a dye-sensitized solar cell such that the structure includes an inlet part exposed to the outside of a reception cell, a delivery part connected to the inlet part and extending in a different direction from the inlet part, and an outlet part connecting the delivery part and the reception cell and extending in a different direction from the delivery part, to substantially increase the overall outer path line of the corresponding electrolyte injection hole, thereby inducing a significant increase in the outer profile of a bonding stopper filled/formed in the electrolyte injection hole, and through this, inducing a large increase in the overall path of a tiny gap formed at an interface between the bonding stopper and the electrolyte injection hole, thereby solving the problems of conventional solar cells such as the immediate outflow, to the outside, of an electrolyte through a tiny gap having a short path and immediate inflow of contaminants (For example, moisture, gas, oil, various types of chemicals, etc.) inside through a tiny gap having a short path, resulting in improved overall product quality.

### Technical Solution

To achieve the above object of the present disclosure, a dye-sensitized solar cell according to an embodiment includes an upper plate and a lower plate, a reception cell interposed between the upper plate and the lower plate and receiving an electrolyte or a dye polymer, and an injection hole configured to inject the electrolyte or the dye polymer from outside of the reception cell into the reception cell, wherein the injection hole includes an inlet part exposed to the outside of the reception cell, a delivery part connected to the inlet part and extending in a different direction from the inlet part, and an outlet part connecting the delivery part and the reception cell and extending in a different direction from the delivery part.

The dye-sensitized solar cell according to the embodiment of the present disclosure may further include a bonding stopper filled in the inlet part, the delivery part and the outlet part of the injection hole, wherein the bonding stopper prevents the outflow of the electrolyte or the dye polymer to the outside of the reception cell, or the inflow of external contaminants into the reception cell.

According to the embodiment of the present disclosure, at least one of the inlet part, the delivery part and the outlet part of the injection hole may include a length extension inducing groove to extend a total length of the injection hole.

According to the embodiment of the present disclosure, a width of the inlet part of the injection hole may be wider than a width of the outlet part of the injection hole.

### Advantageous Effects

The electrolyte injection hole according to an embodiment of the present disclosure includes an inlet part exposed to the outside of a reception cell, a delivery part connected to the inlet part and extending in a different direction from the inlet part, and an outlet part connecting the delivery part and the reception cell and extending in a different direction from the delivery part, thereby increasing the outer length and the surface area in comparison to the conventional injection hole, and through this, inducing a large increase in the outer profile of a bonding stopper filled/formed in the electrolyte injection hole, to substantially increase the overall outer path line. Accordingly, the overall path of a tiny gap formed at an interface between the bonding stopper and the electrolyte injection hole is also significantly increased, thereby solving problems such as the immediate outflow, to the outside, of an electrolyte through a tiny gap having a short path, and the immediate inflow of contaminants (for example, moisture, gas, oil, various types of chemicals, etc.) inside through a tiny gap having a short path, resulting in improved overall product quality.

### DESCRIPTION OF DRAWINGS

FIG. 1 is a diagram showing an example of a conventional dye-sensitized solar cell.

FIG. 2 is a diagram showing an example of a dye-sensitized solar cell according to an embodiment of the present disclosure.

FIGS. 3 to 6 are diagrams showing examples of the shape of electrolyte injection hole according to embodiments of the present disclosure.

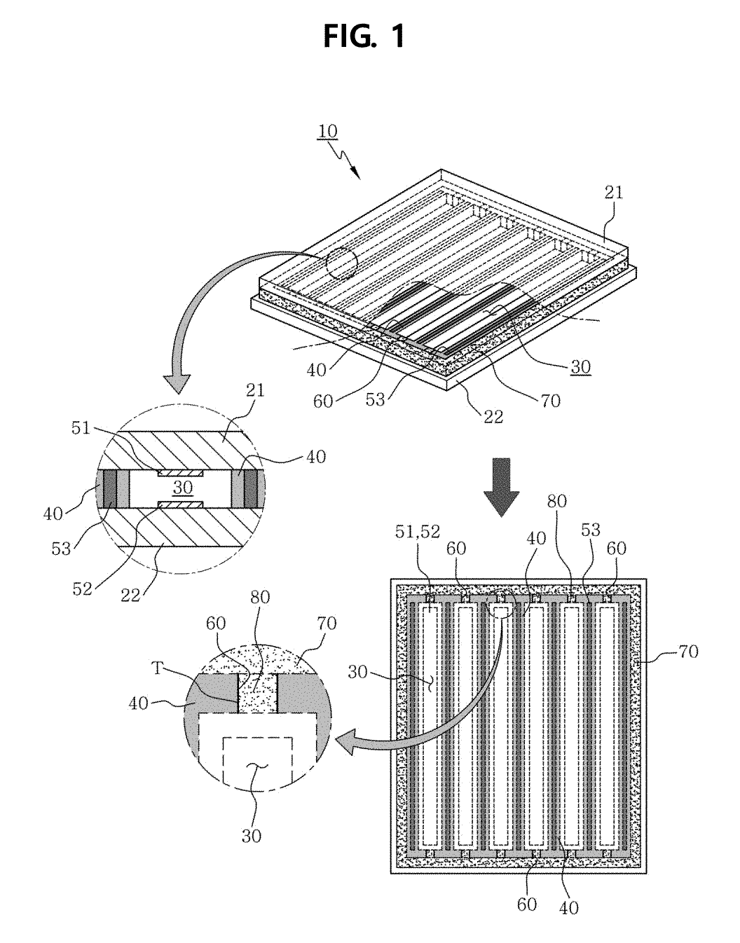

### BEST MODE

Hereinafter, the present disclosure will be described in more detail with reference to the accompanying drawings.

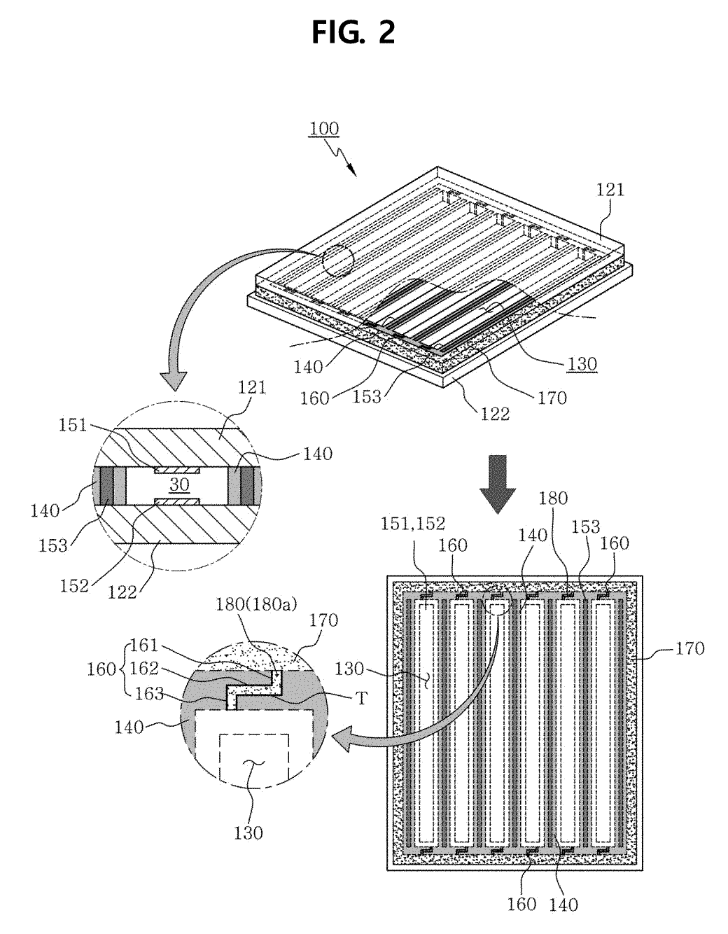

As shown in FIG. 2, a dye-sensitized solar cell 100 according to an embodiment of the present disclosure has a systematic combination of upper and lower plates 121, 122 made of glass with upper and lower electrodes 151, 152, a reception cell 130 interposed between the upper and lower plates 121, 122 and separated by an internal barrier 140 and receiving an electrolyte or a dye polymer, and a grid electrode 153 inserted into the internal barrier 140 and separated from the electrolyte. In this case, the upper and lower plates 121, 122 may be coated with a conductive material (not shown), for example, FTO. A plurality of reception cells 130 may be arranged along the upper and lower plates 121, 122.

When the upper plate 121 and the lower plate 122 that constitute the dye-sensitized solar cell 100 are assembled/combined into a sandwich form by the internal barrier 140, a process of injecting an electrolyte and a dye polymer through an electrolyte injection hole 160 formed on the side of the upper and lower plates 121, 122 is performed at the side of the agent of production.

Unless any separate additional action is taken after injecting the electrolyte and the dye polymer, a serious problem with the outflow of the corresponding electrolyte to the outside may occur, and thus a series of sealing processes is performed at the side of the agent of production to place a sealing structure 170 at the outer periphery of the upper and lower plates 121, 122, thereby preventing the outflow of the electrolyte to the outside.

Furthermore, a bonding stopper 180 is formed in the electrolyte injection hole 160 by performing the steps of applying an organic bonding material 180a to the inlet of the electrolyte injection hole 160, introducing the applied organic bonding material 180a into the electrolyte injection hole 160, and naturally drying and thermally curing the organic bonding material 130a introduced into the electrolyte injection hole 160 at the side of the agent of production, to solve the electrolyte outflow problem and the inflow problem of contaminants (for example, moisture, gas, oil, various types of chemicals, etc.) through the bonding stopper 80.

In this case, when the overall outer path line of the electrolyte injection hole 160 is short, the bonding stopper 180 filled/formed to the size of the electrolyte injection hole 160 also has a short outer profile according to the structure of the electrolyte injection hole 160, and accordingly, a tiny gap T formed at the interface between the bonding stopper 180 and the electrolyte injection hole 160 also has a very short overall path. Eventually, unless any separate action is taken, the problem with the immediate outflow of the electrolyte to the outside through the tiny gap T having a short path and the problem with the immediate inflow of contaminants (for example, moisture, gas, oil, various types of chemicals, etc.) inside through the tiny gap T having a short path occur frequently in the dye-sensitized solar cell 100.

To solve the problem, in an embodiment of the present disclosure, to induce the overall outer path line of the electrolyte injection hole 160 to substantially increase in comparison to the conventional one, as shown in FIG. 2, the electrolyte injection hole 160 is configured to include an inlet part 161 exposed to the outside of the reception cell, a delivery part 162 connected to the inlet part and extending in a different direction from the inlet part, and an outlet part 163 connecting the delivery part and the reception cell and extending in a different direction from the delivery part.

In an embodiment, the inlet part 161 is exposed toward the edge of the upper and lower plates 121, 122, the delivery part 162 is placed horizontally along the edge of the upper and lower plates 121, 122, and the outlet part 163 is connected to the delivery part 162 and exposed to the inside of the upper and lower plates 121, 122.

As described above, when the electrolyte injection hole 160 is composed of a combination of the inlet part 161, the delivery part 162 and the outlet part 163, and the overall outer path line of the corresponding electrolyte injection hole 160 substantially increases in comparison to the conventional one, the bonding stopper 180 filled/formed to the size of the electrolyte injection hole 160 also has the outer profile that is significantly long in comparison to the conventional one by the structural influence of the electrolyte injection hole 160. As a result, the tiny gap T formed at the interface between the bonding stopper 180 and the electrolyte injection hole 160 also has the overall path that is significantly long in comparison to the conventional one.

According to the embodiment of the present disclosure described above, when the overall path of the tiny gap T formed at the interface between the bonding stopper 180 and the electrolyte injection hole 160 is significantly long in comparison to the conventional one, the outflow of the electrolyte in the reception cell interposed between the upper and lower plates 121, 122 to the outside through the tiny gap T having a long path becomes difficult, and eventually, different types of product quality degradation problems caused by the electrolyte outflow to the outside are solved at the side of the agent of production.

Furthermore, according to the embodiment of the present disclosure described above, when the overall path of the tiny gap T formed at the interface between the bonding stopper 180 and the electrolyte injection hole 160 is significantly long in comparison to the conventional one, the inflow of contaminants (for example, moisture, gas, oil, various types of chemicals, etc.) from the outside of the upper and lower plates 121, 122 into the upper and lower plates 121, 122 through the tiny gap T having a long path becomes difficult, and eventually, different types of product quality degradation problems caused by the inflow of contaminants (for example, moisture, gas, oil, various types of chemicals, etc.) can be solved at the side of the agent of production.

As described above, to substantially increase the overall outer path line of the electrolyte injection hole 160 in comparison to the conventional one, the present disclosure configures the structure of the corresponding electrolyte injection hole 160 as a combination of the inlet part 161 exposed to the edge of the upper and lower plates 121, 122, the delivery part 162 placed horizontally along the edge of the upper and lower plates 121, 122, and the outlet part 163 connected to the delivery part 162 and exposed to the inside of the upper and lower plates 121, 122, thereby greatly increasing the outer profile of the bonding stopper 180 filled/formed in the electrolyte injection hole 160, and accordingly, significantly increasing the overall path of the tiny gap T formed at the interface between the bonding stopper 180 and the electrolyte injection hole 160. Eventually, at the side of the agent of production, the problem with the immediate inflow of the electrolyte to the outside through the tiny gap having a short path and the problem with the immediate inflow of contaminants (for example, moisture, gas, oil, various types of chemicals, etc.) inside through the tiny gap having a short path are solved, thereby improving the overall product quality.

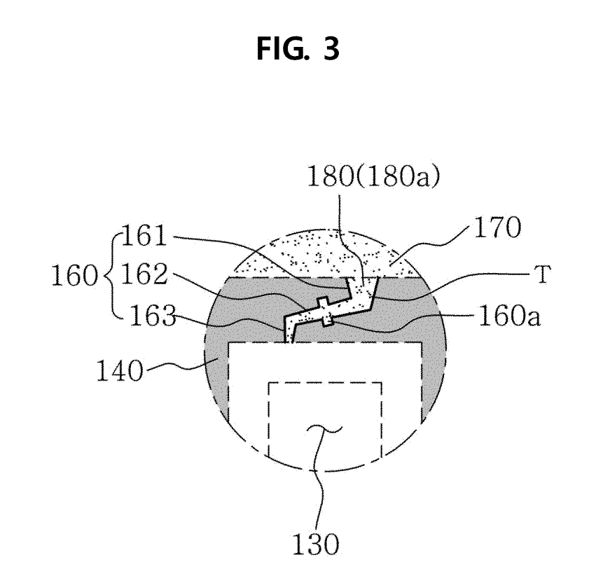

Meanwhile, as shown in FIG. 3, in another embodiment of the present disclosure, a length extension inducing groove 160a may be additionally formed in at least one of the inlet part 161, the delivery part 162 and the outlet part 163 that form the electrolyte injection hole 160 to extend the total length of the electrolyte injection hole 160 (for reference, FIG. 3 shows the case in which the length extension inducing groove 160 is additionally placed at a portion of the delivery part 162).

As described above, when the length extension inducing groove 160a is additionally placed in at least one of the inlet part 161, the delivery part 162 and the outlet part 163 that form the electrolyte injection hole 160 to extend the total length of the electrolyte injection hole 160, the overall outer path line of the electrolyte injection hole 160 further increases in comparison to the above embodiment. Accordingly, the bonding stopper 180 also has a much longer outer profile, and eventually, in this situation, the tiny gap T formed at the interface between the bonding stopper 180 and the electrolyte injection hole 160 also has the overall path that is much longer than that of the above embodiment.

According to another embodiment of the present disclosure described above, when the overall path of the tiny gap T formed at the interface between the bonding stopper 180 and the electrolyte injection hole 160 is much longer than that of the above embodiment, the outflow of the electrolyte in the reception cell interposed between the upper and lower plates 121, 122 to the outside through the tiny gap T having a long path becomes difficult, and eventually, different types of product quality degradation problems caused by the electrolyte outflow to the outside can be solved at the side of the agent of production.

Furthermore, the inflow of contaminants (for example, moisture, gas, oil, various types of chemicals, etc.) from the outside of the upper and lower plates 121, 122, i.e., the outside of the reception cell into the upper and lower plates 121, 122 through the tiny gap T having a long path becomes difficult, and eventually, different types of product quality degradation problems caused by the inflow of contaminants (for example, moisture, gas, oil, various types of chemicals, etc.) can be solved at the side of the agent of production.

Meanwhile, as shown in FIG. 3, the width of the inlet part 161 of the electrolyte injection hole may be wider than the width of the outlet part 163 of the injection hole. In still another embodiment of the present disclosure, the inlet part 161, the delivery part 162 and the outlet part 163 that form the electrolyte injection hole 160 may have a wedge shaped structure with the decreasing width as it goes inwards from the edge of the upper and lower plates 121, 122 (i.e., in the inward direction from the outside of the reception cell).

As described above, when the inlet part 161, the delivery part 162 and the outlet part 163 have a so-called wedge shaped structure with the decreasing width as it goes inward from the edge of the upper and lower plates 121, 122, the bonding stopper 180 filling the inlet part 161, the delivery part 162 and the outlet part 163 naturally forms a tighter contact structure as it goes inward from the edge of the upper and lower plates 121, 122.

As described above, when the bonding stopper 180 filling the inlet part 161, the delivery part 162 and the outlet part 163 is contacted more tightly as it goes inward from the edge of the upper and lower plates 121, 122, the outflow of the electrolyte positioned within the upper and lower plates 121, 122 to the outside through the tight bonding stopper 180 becomes difficult, and eventually, different types of product quality degradation problems caused by the electrolyte outflow to the outside can be solved at the side of the agent of production.

Furthermore, the inflow of contaminants (for example, moisture, gas, oil, various types of chemicals, etc.) from the outside of the upper and lower plates 121, 122 into the upper and lower plates 121, 122 through the tight bonding stopper 180 becomes difficult, and eventually, different types of product quality degradation problems caused by the inflow of contaminants (for example, moisture, gas, oil, various types of chemicals, etc.) can be solved at the side of the agent of production.

The shape of the injection hole according to the embodiment of the present disclosure may be variously modified depending on situations.

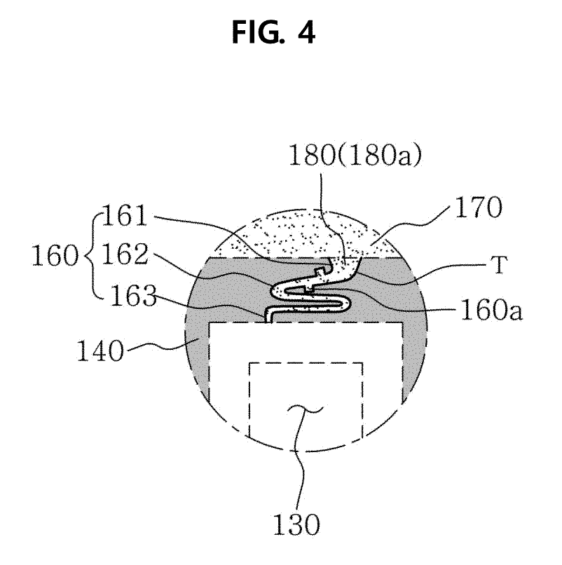

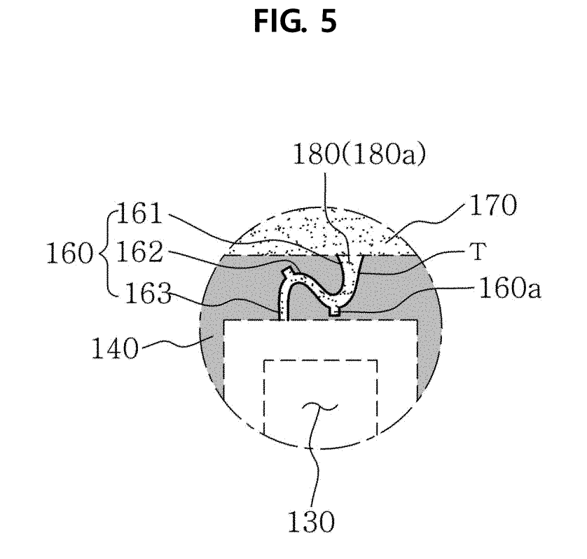

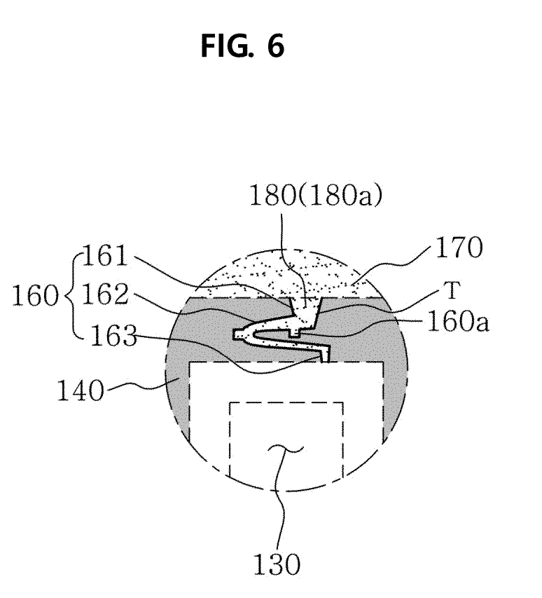

For example, as shown in FIGS. 4 to 6, the electrolyte injection hole 160 may have various modifications to the shape of the inlet part 161, the delivery part 162 and the outlet part 163, for example, S shape and U shape, to substantially increase the overall outer path line in comparison to the conventional one.

In this case, the length extension inducing groove 160a also may be additionally formed in at least one of the inlet part 161, the delivery part 162 and the outlet part 163 that form the electrolyte injection hole 160, to extend the total length of the electrolyte injection hole 160.

Furthermore, in this case, the inlet part 161, the delivery part 162 and the outlet part 163 that form the electrolyte injection hole 160 also may have a wedge shaped structure with the decreasing width of the injection hole as it goes inward from the edge of the upper and lower plates 121, 122.

According to each of these embodiments, the overall outer path line of the electrolyte injection hole 160, the outer profile of the bonding stopper 180 filled/formed in the electrolyte injection hole 160, and the overall path of the tiny gap T formed at the interface between the bonding stopper 180 and the electrolyte injection hole 160 significantly increase in comparison to those of the conventional art, thereby solving problems such as the immediate outflow, to the outside, of the electrolyte through a tiny gap having a short path and the immediate inflow of contaminants (for example, moisture, gas, oil, various types of chemicals, etc.) inside through a tiny gap having a short path, resulting in improved overall product quality.

The present disclosure is not limited to a particular field, and generally exerts useful effects in many fields requiring electrolyte leak prevention.

While the present disclosure have been hereinabove described with reference to the embodiments shown in the drawings, this is for illustrative purposes only and it will be understood by those skilled in the art that various modifications in form and details may be made thereto. However, it should be noted that such modifications fall within the technical scope of protection of the present disclosure. Therefore, the true technical scope of protection of the present disclosure should be defined by the technical spirit of the appended claims.

### INDUSTRIAL APPLICABILITY

The electrolyte injection hole according to an embodiment of the present disclosure includes the inlet part exposed to the outside of the reception cell, the delivery part connected to the inlet part and extending in a different direction from the inlet part, and the outlet part connecting the delivery part and the reception cell and extending in a different direction from the delivery part. Thus, it results in an increase in the outer length and the surface area in comparison to the conventional injection hole, through this, inducing a large increase in the outer profile of the bonding stopper filled/formed in the electrolyte injection hole, to substantially increase the overall outer path line. Accordingly, the overall path of the tiny gap formed at the interface between the bonding stopper and the electrolyte injection hole is also significantly increased, thereby solving problems such as the immediate outflow, to the outside, of an electrolyte through a tiny gap having a short path, and the immediate inflow of contaminants (for example, moisture, gas, oil, various types of chemicals, etc.) inside through a tiny gap having a short path. As described above, the quality of the dye-sensitized solar cell is improved by a relatively simple method, and thus it will be used in a wide range of applications in fabricating dye-sensitized solar cells.

1. A dye-sensitized solar cell, comprising:
an upper plate and a lower plate;
a reception cell interposed between the upper plate and the lower plate, and receiving an electrolyte or a dye polymer; and
an injection hole configured to inject the electrolyte or the dye polymer from outside of the reception cell into the reception cell,
wherein the injection hole comprises:
an inlet part exposed to the outside of the reception cell;
a delivery part connected to the inlet part, and extending in a different direction from the inlet part; and
an outlet part connecting the delivery part and the reception cell, and extending in a different direction from the delivery part.

2. The dye-sensitized solar cell according to claim 1, further comprising:
a bonding stopper filled in the inlet part, the delivery part and the outlet part of the injection hole,
wherein the bonding stopper prevents the outflow of the electrolyte or the dye polymer to the outside of the reception cell, or the inflow of external contaminants into the reception cell.

3. The dye-sensitized solar cell according to claim 1, wherein at least one of the inlet part, the delivery part and the outlet part of the injection hole includes a length extension inducing groove to extend a total length of the injection hole.

4. The dye-sensitized solar cell according to claim 1, wherein a width of the inlet part of the injection hole is wider than a width of the outlet part of the injection hole.
